(19) United States
(12) Patent Application Publication
(10) Pub. No.: US 2013/0170281 A1
(43) Pub. Date: Jul. 4, 2013

(54) VARIABLE RESISTANCE MEMORY DEVICE AND METHOD FOR FABRICATING THE SAME

(71) Applicants: Seok-Pyo Song, Gyeonggi-do (KR); Sung-Woong Chung, Gyeonggi-do (KR); Su-Ock Chung, Gyeonggi-do (KR); Dong-Joon Kim, Gyeonggi-do (KR)

(72) Inventors: Seok-Pyo Song, Gyeonggi-do (KR); Sung-Woong Chung, Gyeonggi-do (KR); Su-Ock Chung, Gyeonggi-do (KR); Dong-Joon Kim, Gyeonggi-do (KR)

(21) Appl. No.: 13/595,710

(22) Filed: Aug. 27, 2012

(30) Foreign Application Priority Data
Dec. 29, 2011 (KR) 10-2011-0146050

(51) Int. Cl. H01L 45/00; G11C 11/00

(52) U.S. Cl. 365/148; 257/1; 438/381; 438/3; 257/E45.002

(57) ABSTRACT

A variable resistance memory device includes a semiconductor substrate having an active area defined by an isolation layer extending in one direction, a gate line extending in another direction crossing the isolation layer through the isolation layer and the active area, a protective layer located over the gate line, a contact plug positioned in a partially removed space of the active area between the protective layers, and a variable resistance pattern coupled to a part of the contact plug.

### CROSS-REFERENCE TO RELATED APPLICATIONS

The present application claims priority of Korean Patent Application No. 10-2011-0146050, filed on Dec. 29, 2011, which is incorporated herein by reference in its entirety.

### BACKGROUND

1. Field

Exemplary embodiments of the present invention relate to a variable resistance memory device and a method for fabricating the same, and more particularly, to a variable resistance memory device and a method for fabricating the same, which uses a self-aligned contact process.

2. Description of the Related Art

A variable resistance memory device stores data using a characteristic in which the resistance thereof is changed according to an external stimulus and switched between two different resistance states. The variable resistance memory device may include Resistive Random Access Memory (ReRAM), Phase Change RAM (PCRAM), Spin Transfer Torque-RAM (STT-RAM), and the like.

FIG. 1 is a plan view illustrating the layout of a conventional variable resistance memory device. FIGS. 2A to 2D are cross-sectional views explaining a method for fabricating the conventional variable resistance memory device. The cross-sectional views are taken along lines A-A′ and B-B′ of FIG. 1.

Referring to FIG. 2A, a line-shaped isolation layer 15 is formed over a semiconductor substrate 10 so as to extend in the A-A′ direction, thereby defining an active area 10A.

Subsequently, a gate line 20 is formed so as to extend in a B-B′ direction through the active area 10A and the isolation layer 15. A gate line protection layer 25 is formed over the gate line 20.

Referring to FIG. 2B, a first insulation layer 30 is formed over the resultant structure. Then, the first insulation layer 30 is partially etched to form a first contact hole which exposes the active area 10A.

A first contact plug 35 is formed in the first contact hole. The first contact plug 35 includes an ohmic contact layer 35A and a metal layer 35B over the ohmic contact layer 35A.

Referring to FIG. 2C, a second insulation layer 40 is formed over the first insulation layer 30 and the first contact plug 35. Then, the second insulation layer 40 is selectively etched to form a second contact hole which exposes the first contact plug 35 to be coupled a source line 55 which will be described below.

A second contact plug 45 is buried in the second contact hole. A third insulation layer 50 is formed over the second insulation layer 40 and the second contact plug 45.

The third insulation layer 50 is selectively etched to form line-shaped trenches which extend in the same direction as the active area 10A while exposing the second contact plug 45. Then, a source line 55 is buried in the trenches. A source line protection layer 60 is formed over the source line 55. At this time, the source line 55 should be formed at a predetermined height or more, in order to prevent an increase of line resistance.

Referring to FIG. 2D, a fourth insulation layer 65 is formed over the resultant structure. A third contact plug 70 is formed to be coupled to a part of the first contact plug 35 through the fourth insulation layer 65.

Subsequently, a variable resistance pattern 75 is formed over the third contact plug 70.

In the conventional variable resistance memory device, the third contact plug 70 coupled to the variable resistance pattern 75, which is constituted with memory cells in the variable resistance memory device, has a high aspect ratio. Therefore, the conventional variable resistance memory device is difficult to fabricate, and has high resistance. Furthermore, due to misalignment of mask patterns, contact resistance may rapidly increase, or a contact area may be not open.

### SUMMARY

An embodiment of the present invention is directed to a variable resistance memory device, which reduces resistance between a variable resistance pattern forming memory cells and an active area becoming a source or drain area of a transistor, and a method for fabricating the same.

In accordance with an embodiment of the present invention, a variable resistance memory device includes: a semiconductor substrate having an active area defined by an isolation layer extending in one direction; a gate line extending in another direction crossing the isolation layer through the isolation layer and the active area; a protective layer located over the gate line; a contact plug positioned in a partially removed space of the active area between the protective layers; and a variable resistance pattern coupled to a part of the contact plug.

In accordance with another embodiment of the present invention, a method for fabricating a variable resistance memory device includes: providing a semiconductor memory device having an active area defined by an isolation layer extending in one direction; forming a trench extending in a direction crossing the isolation layer by selectively etching the isolation layer and the active area; forming a gate line and a protective layer over the gate line in the trench; forming a contact hole by partially etching the active area between the protective layers; forming a contact plug in the contact hole; and forming a variable resistance pattern coupled to a part of the contact plug.

In accordance with another embodiment of the present invention, a semiconductor device includes: a variable resistance pattern configured to store data with non-volatility; a bit line configured to deliver data to/from the variable resistance pattern; a word line configured to control data delivery between the bit line and the variable resistance pattern, including a buried gate line located at a level under a top surface of semiconductor substrate; and a source line configured to supply operational voltage to the variable resistance pattern, wherein a physical distance between the word line and the variable resistance pattern is shorter than that between the word line and the bit line.

### BRIEF DESCRIPTION OF THE DRAWINGS

FIG. 1 is a plan view illustrating the layout of a conventional variable resistance memory device.

FIGS. 2A to 2D are cross-sectional views explaining a method for fabricating the conventional variable resistance memory device.

FIG. 3 is a plan view illustrating the layout of variable resistance memory devices in accordance with an embodiment of the present invention.

FIGS. 4A to 4I are cross-sectional views explaining a variable resistance memory device and a method for fabricating the same in accordance with an embodiment of the present invention.

FIG. 5 is a cross-sectional view explaining a variable resistance memory device and a method for fabricating the same in accordance with an embodiment of the present invention.

FIG. 6 is a block diagram of an information processing system using the variable resistance memory device in accordance with an embodiment of the present invention.

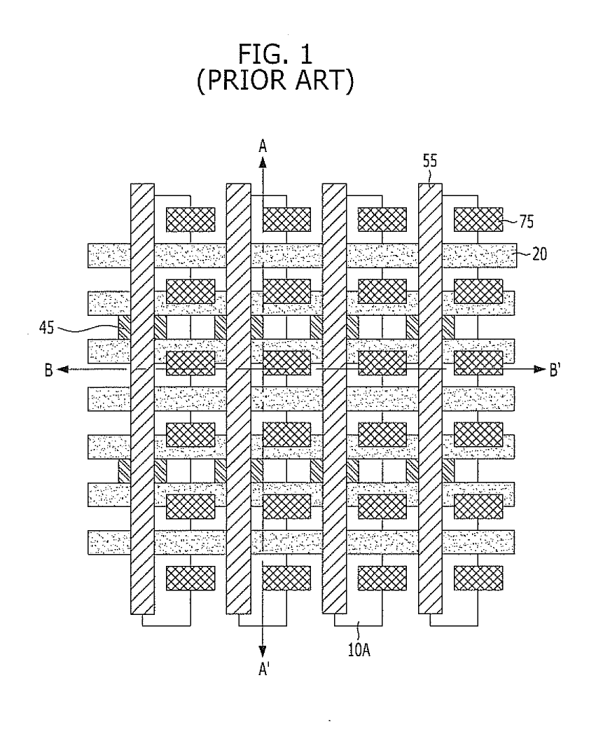

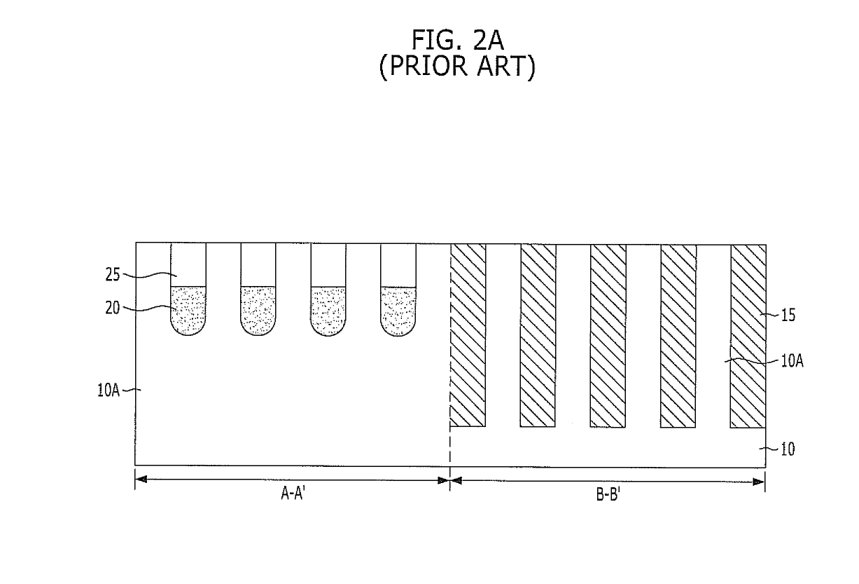

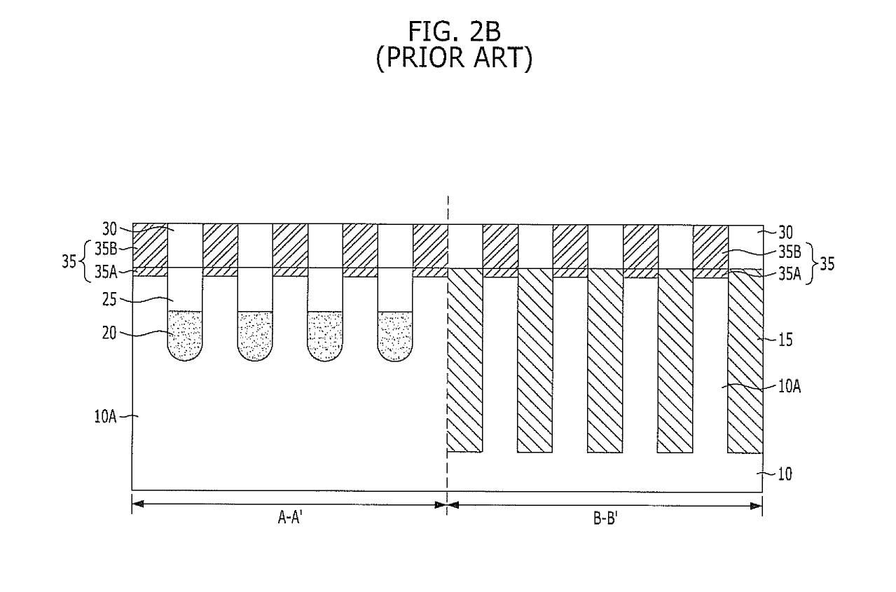

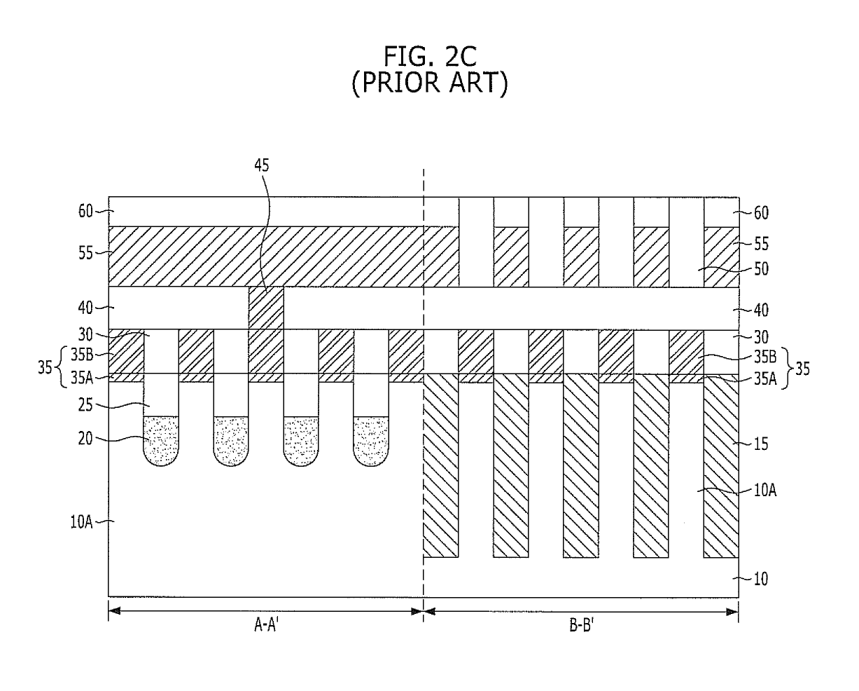

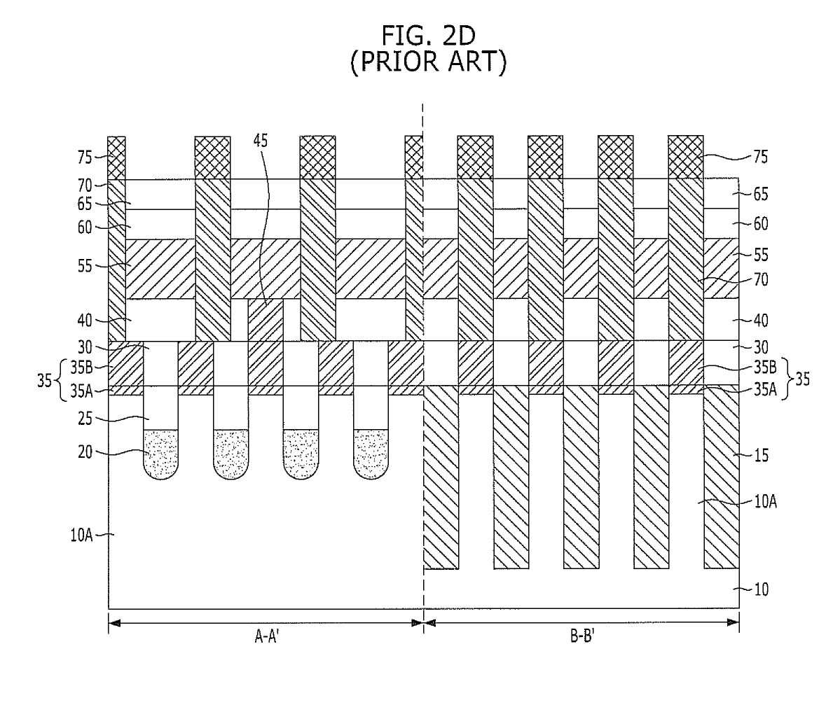

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

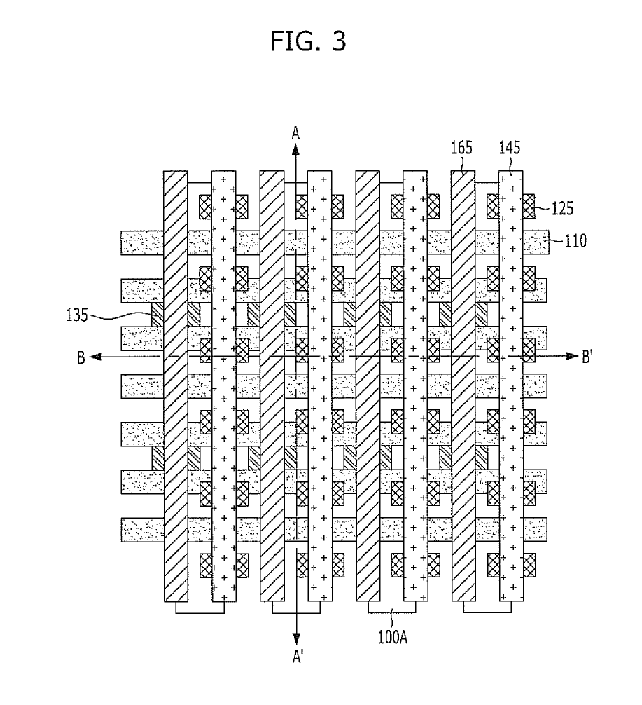

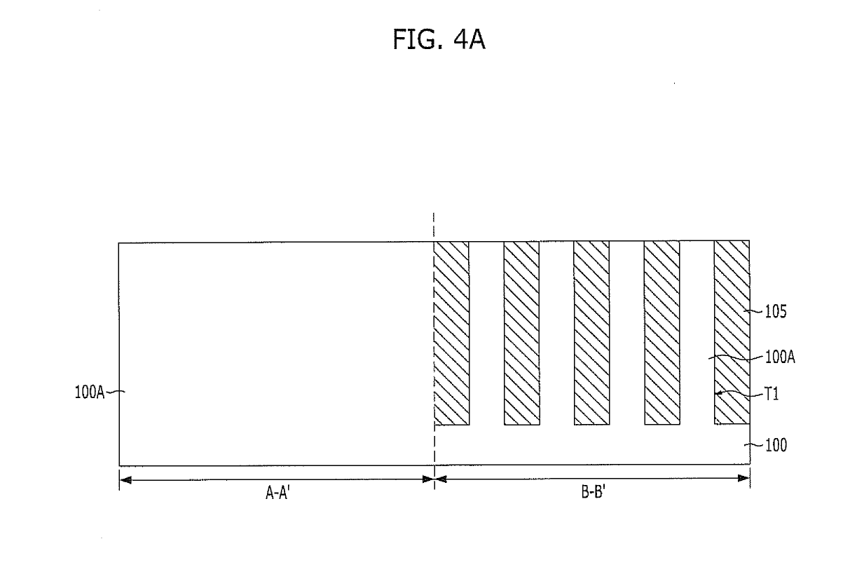

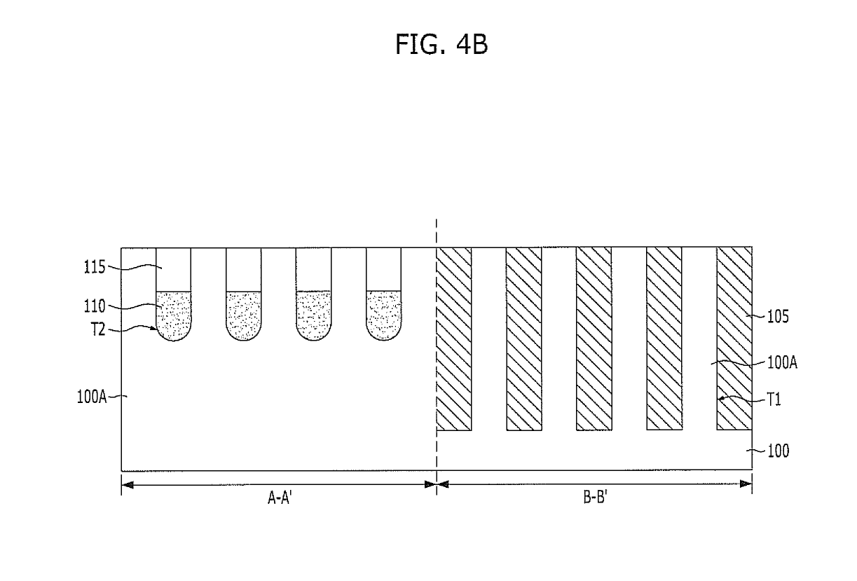

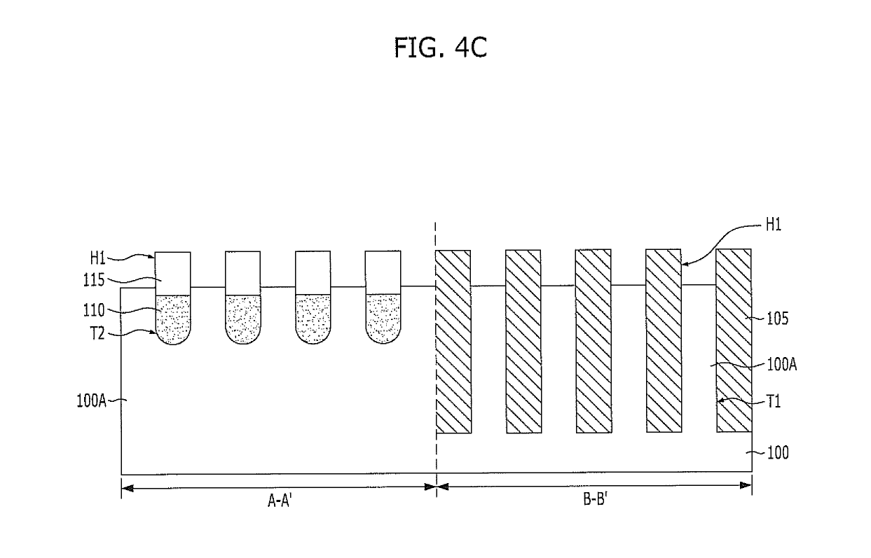

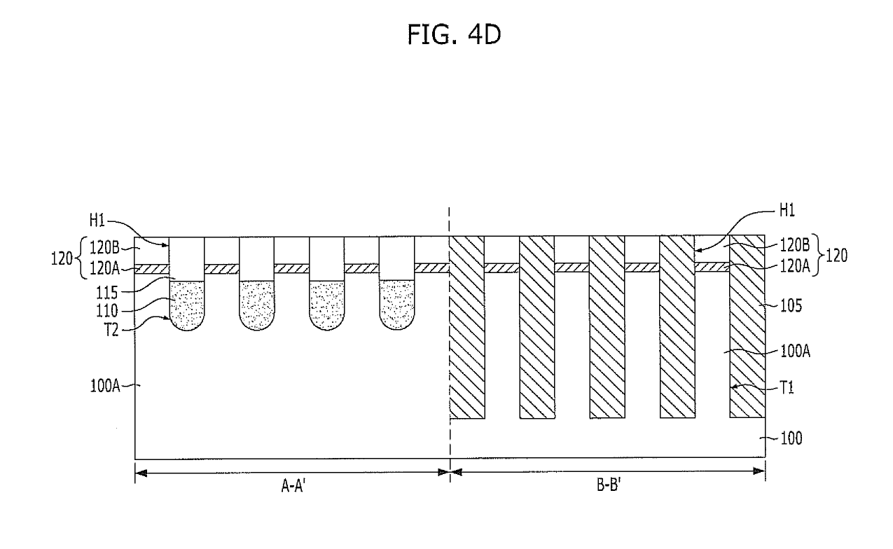

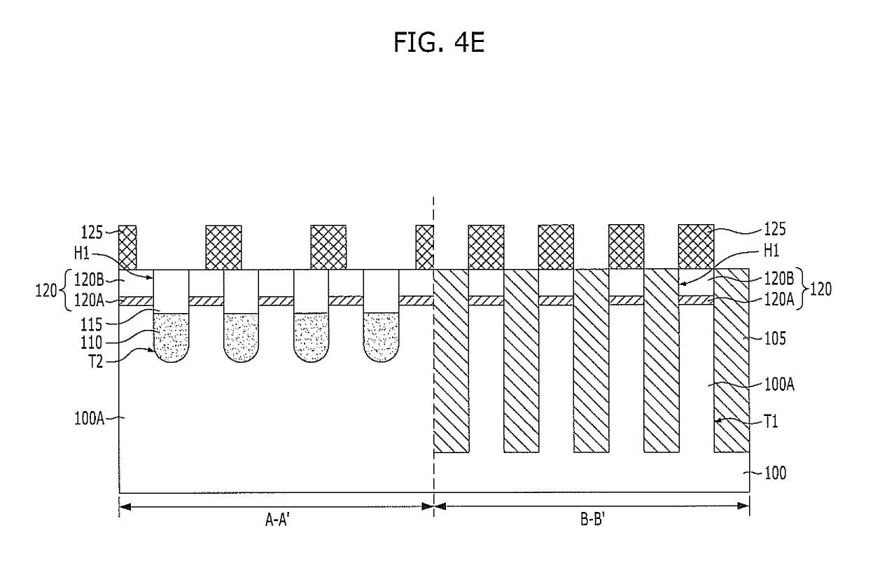

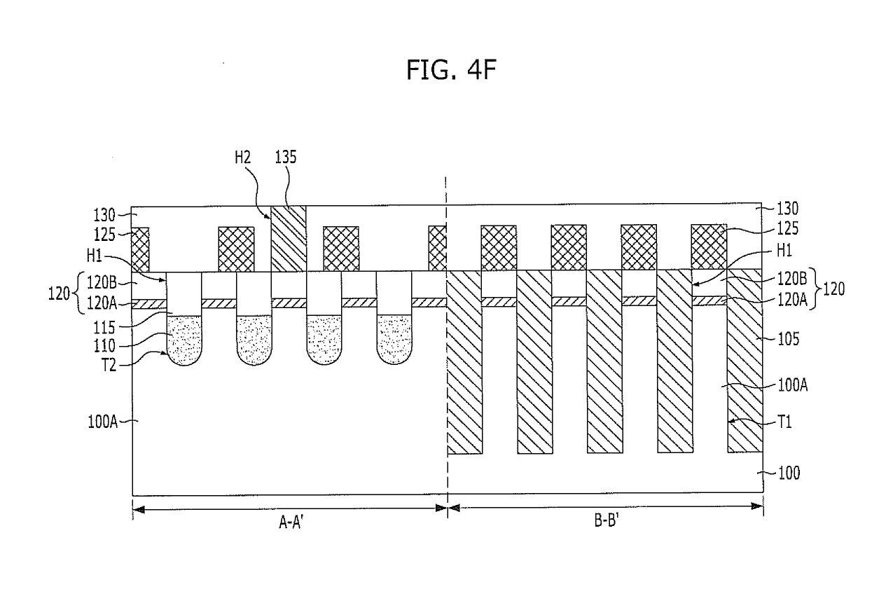

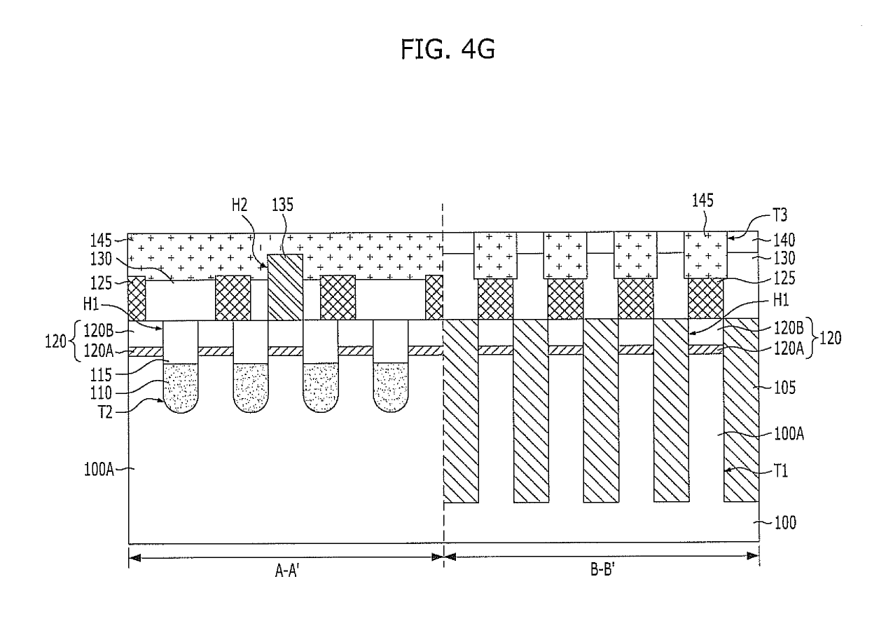

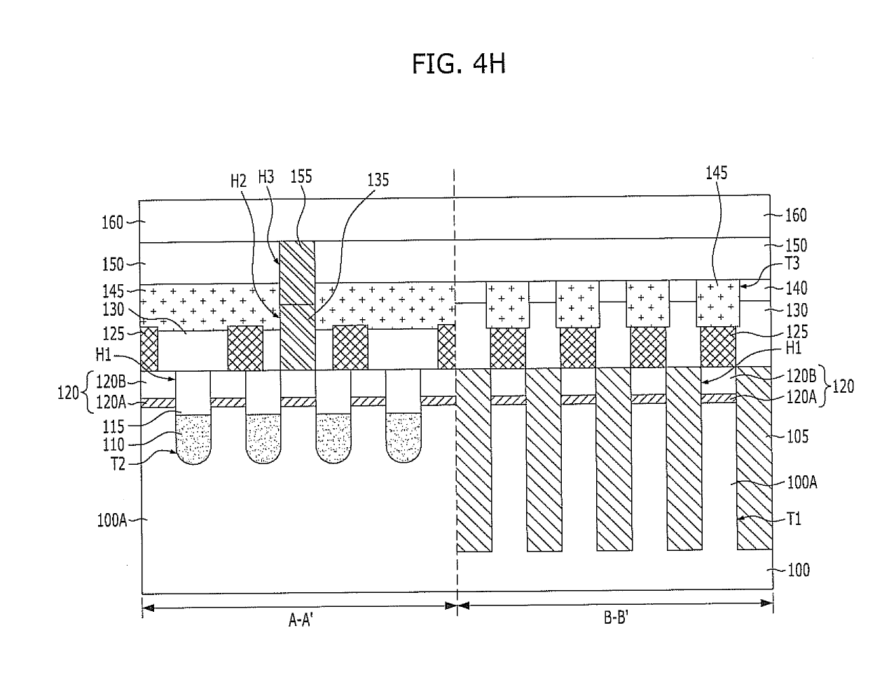

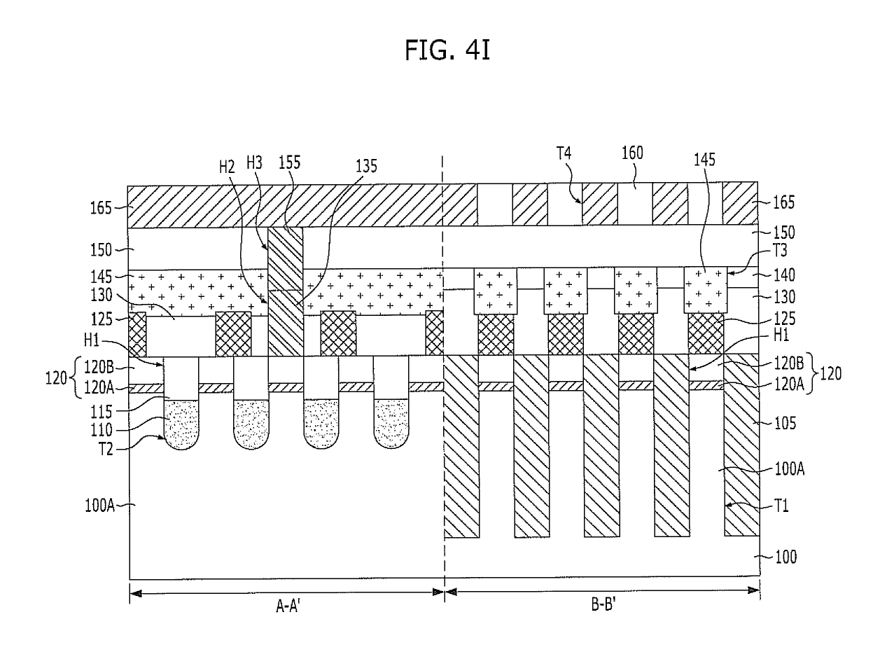

FIG. 3 is a plan view illustrating the layout of variable resistance memory devices in accordance with an embodiment of the present invention. FIGS. 4A to 4I are cross-sectional views explaining a variable resistance memory device and a method for fabricating the same in accordance with an embodiment of the present invention. In particular, FIG. 4I is a cross-sectional view of the variable resistance memory device in accordance with the embodiment of the present invention. FIGS. 4A and 4H are cross-sectional views illustrating intermediate processes for fabricating the device of FIG. 4I. The cross-sectional views are taken along lines A-A′ and B-B′ of FIG. 3.

Referring to FIG. 4A, a line-shaped mask pattern (not illustrated) extending in the A-A′ direction is formed over a semiconductor substrate 100. The semiconductor substrate 100 is partially etched using the mask pattern as an etching mask, thereby forming a plurality of isolation trenches T1. The semiconductor substrate 100 may include a single crystal silicon substrate. The plurality of isolation trenches T1 are arranged in parallel to each other.

An insulation material having an etching selectivity with the semiconductor substrate 100 is formed over the semiconductor substrate 100 having the isolation trenches T1 formed therein by one or more methods of Spin On Dielectric (SOD), High Aspect Ratio Process (HARP), and High Density Plasma (HDP). The insulation material is formed to such a thickness as to fill the isolation trenches T1. Then, an isolation layer 105 is formed by performing a planarization process such as chemical mechanical polishing (CMP) until the top surface of the semiconductor substrate 100 is exposed. Meanwhile, an active area 100A is defined by the isolation layer 105 according to the result of this process. The active area 100A may include a source or drain area of a transistor.

In particular, the width of the active area 100A may be set to be larger than that of a gate line. In this case, the magnitude of a current flowing in a transistor may be increased. Parasitic resistance may be reduced to sufficiently secure a sensing margin of data stored in memory cells formed by a variable resistance pattern.

Referring to FIG. 4B, a line-shaped mask pattern (not illustrated) extending in the B-B′ direction is formed over the active area 100A and the isolation layer 105. The active area 100A and the isolation layer 105 are partially etched using the mask pattern as an etching mask, thereby forming a plurality of gate line trenches T2. The plurality of gate line trenches T2 may be arranged in parallel. Considering the difficulty degree of the subsequent process, the plurality of gate line trenches T2 may be formed to cross the active area 100A at an angle of 60° to 120°, for example, when seen from the top.

A gate dielectric layer (not illustrated) is formed on the surface of the gate line trenches T2. A gate line 110 is formed to partially fill the gate line trenches T2. The gate dielectric layer may include silicon oxide (SiO₂), silicon oxynitride (SiOₓN_{y}), or a high-k thin film, for example.

Specifically, the gate line 110 may be formed according to the following process. First, metal nitride such as titanium nitride (TiN) is conformally deposited on the gate dielectric layer so as to form a barrier metal. A metallic material, such as tungsten (W), copper (Cu) or aluminum (Al), or a carbon compound having low specific resistance is deposited at such a thickness as to fill the gate line trenches T2, thereby forming a gate conductive layer (not illustrated). Then, a planarization process such as CMP is performed until the top surface of the active area 100A is exposed. The gate conductive layer is additionally etched back to form the buried gate line 110.

A protective layer 115 is formed over the gate line 110. The protective layer 115 may be formed by the following process: an insulation material having an etching selectivity with the semiconductor substrate 100 is deposited at such a thickness as to fill the gate line trenches T2 having the gate line 110 formed therein. A planarization process such as CMP is performed until the top surface of the active area 100A is exposed.

Referring to FIG. 4C, the active area 100A between the protective layers 115 is partially etched to form a self-alignment contact hole H1. At this time, a part of the active area 100A may be selectively removed by using different etching selectivities between the active area 100A and the protective layer 115, and between the active area 100A and the isolation layer 105.

In succession, junction regions (not illustrated) may be formed in the active area 100A between the gate lines 110 through an ion implantation process, and so forth. The junction regions serve as the drains or the sources of the memory cell transistors, and may have a conductivity type different from that of the active area 100A.

In particular, since the variable resistance memory device does not accumulate electric charges to store data unlike DRAM or the like, a constraint condition for leakage current of a transistor is eased. Therefore, the distance between a channel and a source/drain may be reduced in the thickness direction of the gate line trenches T2, which makes it possible to reduce internal resistance of the transistor.

Referring to FIG. 4D, a contact plug 120 is buried in the self-alignment contact hole H1. The contact plug 120 may include an ohmic contact layer 120A and a metal layer 120B over the ohmic contact layer 120A. Specifically, the contact plug 120 may be formed by the following process.

First, the ohmic contact layer 120A is formed over the active area 100A corresponding to the bottom surface of the self-alignment contact hole H1. The ohmic contact layer 120A may include titanium silicide (TiSiₓ), cobalt silicide (CoSiₓ), nickel silicide (NiSiₓ), or the like. Such a metal silicide may be formed by the following processes. A metallic material such as Ti, Co, or Ni is deposited. A heat treatment such as RTA (Rapid Thermal Annealing) is performed to form the metal silicide.

The metal layer 120B is formed over the ohmic contact layer 120A. The metal layer 120B may include one or more conductive materials selected from the group consisting of metallic materials such as Ti, Ta, W, Cu, and Al and metal nitrides such as TIN, TaN, and WN. The metal layer 120B maybe formed by the following processes. A metallic material or/and a metal nitride is/are deposited to such a thickness as to fill the self-alignment contact hole H1 having the ohmic contact layer 120A formed therein. A planarization process such as CMP is performed until the top surface of the protective layer 115 is exposed.

Referring to FIG. 4e, a variable resistance pattern 125 is formed to be coupled to one part of the contact plug 120. The other part of the contact plug 120 is to be coupled to a first source line contact plug which will be described below. The variable resistance pattern 125 may have an island shape that is arranged in a matrix shape, when seen from the top.

In particular, the variable resistance pattern 125 may include a magnetic tunnel junction (MTJ) structure having electrical resistance changed by a magnetic field or spin transfer torque (STT), or another structure having electrical resistance changed by migration of oxygen vacancies or ions or phase change of a material.

Here, the MTJ structure may include a magnetic free layer, a magnetic fixed layer, and a barrier layer interposed between the magnetic free layer and the magnetic fixed layer. The magnetic free layer and the magnetic fixed layer may include ferromagnetic substances, such as Fe, Ni, Co, Gd and Dy, or a compound thereof. The barrier layer may include magnesium oxide (MgO), aluminum oxide (Al₂O₃), hafnium oxide (HfO₂), zirconium oxide (ZrO₃), silicon oxide (SiO₂), and so on.

Furthermore, the structure whose electric resistance is changed by phase change of a material may include a material having a solid state changed based on heat into a crystalline or amorphous state, for example, a chalcogenide-based material such as GST (GeSbTe) in which germanium, antimony, and tellurium are combined at a predetermined ratio. The structure whose electric resistance is changed by migration of oxygen vacancies or ions may include perovskite-based materials, such as STO (SrTiO₃), BTO (BaTiO₃) and PCMO (Pr₁₋ₓCaₓMnO₃), or transmission metal oxides (TMO) such as TiO₂, HfO₂, Al₂O₃, tantalum oxide (Ta₂O₅), niobium oxide (Nb₂O₅), Co₃O₄, WO₃, and lanthanum oxide (La₂O₃).

In order to prevent the variable resistance pattern 125 from being shorted to a first source line contact plug which will be described, a spacer layer (not illustrated) including a nitride-based material may be formed over the resultant structure having the variable resistance pattern 125 formed therein.

Referring to FIG. 4F, a first insulation layer 130 is formed over the resultant structure having the variable resistance pattern 125 formed therein. The first insulation layer 130 may include one or more oxide-based materials among SiO₂, Tetra Ethyl Ortho Silicate (TEOS), Boron Silicate Glass (BSG), Phosphorus Silicate Glass (PSG), Fluorinated Silicate Glass (FSG), Boron Phosphorus Silicate Glass (BPSG), and Spin On Glass (SOG). At this time, the top surface of the first insulation layer 130 may be set at a higher level than the top surface of the variable resistance pattern 125, and may be planarized through CMP or the like.

The first insulation layer 130 is selectively etched to form a first source line contact hole H2 which exposes the top surface of the contact plug 120 which is not coupled to the variable resistance pattern 125. A first source line contact plug 135 is formed in the first source line contact hole H2. The first source line contact plug 135 may include one or more conductive materials selected from the group consisting of metallic materials, such as Ti, Ta, W, Cu and Al, and metal nitrides such as TiN, TaN, and WN. The first source line contact plug 135 may be formed by the following processes. A conductive material is deposited to such a thickness as to fill the first source line contact hole H2. A planarization process such as CMP is performed until the top surface of the first insulation layer 130 is exposed.

Referring to FIG. 4G, a second insulation layer 140 is formed over the first insulation layer 130 and the first source line contact plug 135. The second insulation layer 140 may include one or more oxide-based materials among SiO₂, TEOS, BSG, PSG, FSG, BPSG, and SOG.

A line-shape mask pattern (not illustrated) is formed over the second insulation layer so as to expose an area in which a bit line 145 is to be formed. The first and second insulation layers 130 and 140 are partially etched using the mask pattern as an etching mask, thereby forming a plurality of bit line trenches T3. The plurality of bit line trenches T3 may be extended in the same direction as the active area 100A while exposing the top surface of the variable resistance pattern 125. The plurality of bit line trenches T3 may be arranged in parallel.

The bit line 145 is buried in the bit line trenches T3. The bit line 145 may include one or more conductive materials selected from the group consisting of metallic materials, such as Ti, Ta, W, Cu, and Al, and carbon compounds having low specific resistance. The bit line 145 may be formed by the following processes. A conductive material is deposited to such a thickness as to fill the bit line trench T3. A planarization process such as CMP is performed until the top surface of the second insulation layer 140 is exposed.

Referring to FIG. 4H, a third insulation layer 150 is formed over the resultant structure having the bit line 145 formed therein. The third insulation layer 150 may include one or more oxide-based materials among SiO₂, TEOS, BSG, PSG, FSG, BPSG, and SOG.

The third insulation layer 150 is selectively etched to form a second source line contact hole H3 which exposes the top surface of the first source line contact plug 135. A second line contact plug 155 is formed in the second line contact hole H3. The second line contact plug 155 may include one or more conductive materials selected from the group consisting of metallic materials, such as Ti, Ta, W, Cu and Al, and metal nitrides TiN, TaN, and WN. The second line contact plug 155 may be formed by the following processes. A conductive material is deposited to such a thickness as to fill the second source line contact hole H3. A planarization process such as CMP is performed until the top surface of the third insulation layer 150 is exposed.

A fourth insulation layer 160 is formed over the third insulation layer 150 and the second source line contact plug 155. The fourth insulation layer 160 may include one or more oxide-based materials among SiO₂, TEOS, BSG, PSG, FSG, BPSG, and SOG.

Referring to FIG. 4I, a line-shaped mask pattern (not illustrated) is formed over the fourth insulation layer 160 so as to expose an area where a source line 165 is to be formed. The fourth insulation layer 160 is etched using the mask pattern using an etch mask, thereby forming a plurality of source line trenches T4. The plurality of source line trenches T4 may be extended in the same direction as the active area 100A while exposing the top surface of the second source line contact plug 155. The plurality of source line trenches T4 may be arranged in parallel.

A source line 165 is buried in the source line trenches T4. The source line 165 may include one or more conductive materials, selected from the group consisting of Ti, Ta, W, Cu, and Al, and carbon compounds having low specific resistance. The source line 165 may be formed by the following processes. A conductive material is deposited to such a thickness as to fill the source line trenches T4. A planarization process such as CMP is performed until the top surface of the fourth insulation layer 160 is exposed.

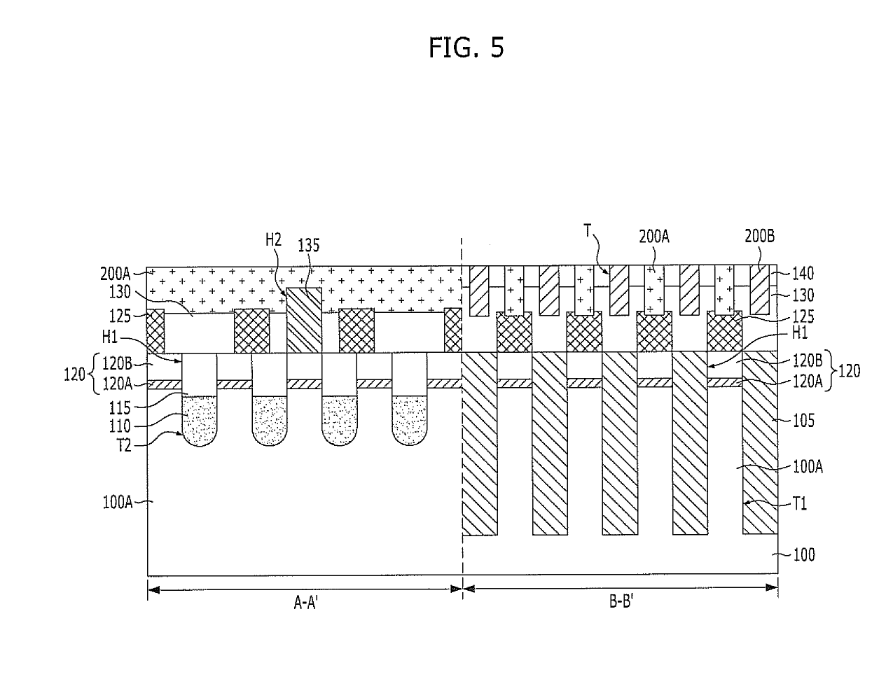

FIG. 5 is a cross-sectional view explaining a variable resistance memory device and a method for fabricating the same in accordance with an embodiment of the present invention. The cross-sectional views are taken along lines A-A′ and B-B′ of FIG. 3. In the embodiment of the present invention, the detailed descriptions of the same components as those of the above-described embodiment of the present invention are omitted herein. First, after the processes of FIGS. 4A to 4F are performed in the same manner as the above-described embodiment of the present invention, a process of FIG. 5 is performed.

Referring to FIG. 5, the second insulation layer 140 is formed over the first insulation layer 130 and the first source line contact plug 135. The second insulation layer 140 may include one or more oxide-based materials among SiO₂, TEOS, BSG, PSG, FSG, BPSG, and SOG.

Subsequently, a line-shaped mask pattern (not illustrated) is formed over the second insulation layer 140 so as to expose an area where a bit line 200A and a source line 200B are to be formed. The first and second insulation layers 130 and 140 are partially etched using the mask pattern as an etching mask, thereby forming a plurality of trenches T. The plurality of trenches T may be extended in the same direction as the active area 100A while exposing the variable resistance pattern 125 or the first source line contact plug 135. The plurality of trenches T may be arranged in parallel.

The bit line 200A and the source line 2008 are formed in the trenches T so as to be coupled to the variable resistance pattern 125 and the first source line contact plug 135, respectively. The bit line 200A and the source line 200E may include one or more conductive materials, selected from the group consisting of metallic materials such as Ti, Ta, W, Cu and Al, and carbon compounds having low specific resistance. The bit line 200A and the source line 200B may be formed by the following processes. A conductive material is deposited to such a thickness as to fill the trenches T. A planarization process such as CMP is performed until the top surface of the second insulation layer 140 is exposed.

In the second embodiment of the present invention, since the bit line 200A and the source line 2008 are formed at once over the same plane, the process may be further simplified. At this time, the EUV (Extreme Ultraviolet) lithography or spacer patterning technology may be used to pattern a line having a smaller CD.

The variable resistance memory device in accordance with the embodiments of the present invention, as illustrated in FIGS. 3, 4I, and 5, may be fabricated by the above-described method.

Referring to FIGS. 3, 4I, and 5, the variable resistance memory device in accordance with the first and second embodiments of the present invention includes the semiconductor substrate 100, the gate line 110, the protective layer 115, the contact plug 120, the variable resistance pattern 125, the bit line 145, the bit line 145, and the source line 165. The semiconductor substrate 100 includes the active area 100A defined by the isolation layer 105 extending in the A-A′ direction. The gate line 110 extends in the B-B′ direction through the isolation layer 105 and the active area 100A. The protective layer 115 is formed over the gate line 110. The contact plug 120 positioned in a space obtained by partially removing the active area 100A between the protective layers 115. The variable resistance pattern 125 is coupled to the contact plug 120. The bit line 145 extends in the A-A′ direction while coupled to the source line contact plug and the variable resistance pattern 125. The source line 165 extends in the A-A′ direction while coupled to the source line contact plug.

The active area 100A may have a larger width than the width of the gate line 110. The active area 100A may cross the gate line 100 at an angle of about 60° to about 120°.

The isolation layer 105 and the protective layer 115 may be formed of a material having an etching selectivity with the active area 100A. The contact plug 120 may include the ohmic contact layer 120A and the metal layer 120B over the ohmic contact layer 120A.

The variable resistance pattern 125 may include an MTJ structure having electrical resistance changed based on a magnetic field or STT or another structure having electrical resistance changed by migration of oxygen vacancies or ions or phase change of a material.

The source line contact plug may include the first and second source line contact plugs 135 and 155. The source line contact plug may have a larger height than the variable resistance pattern 125.

The source line 165 may be formed at a higher position than the bit line 145 or positioned on the same plane as the bit line 145.

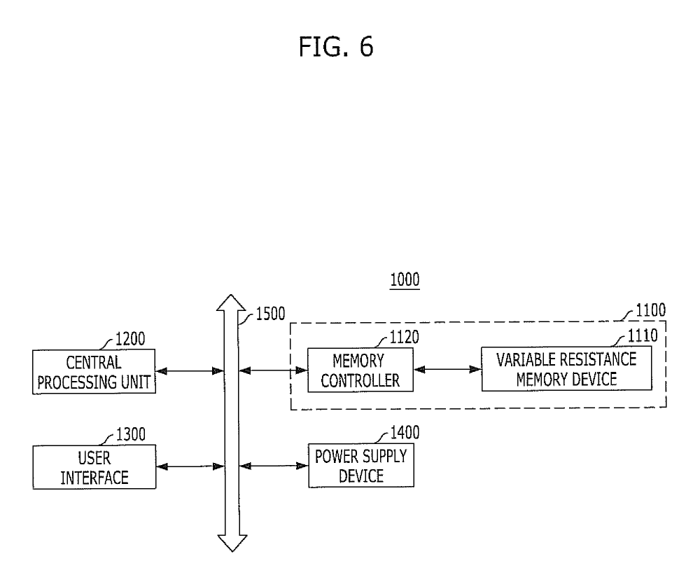

FIG. 6 is a block diagram of an information processing system using the variable resistance memory device in accordance with the embodiments of the present invention.

Referring to FIG. 6, the information processing system 1000 using the variable resistance memory device in accordance with the embodiments of the present invention includes a memory system 1100, a central processing unit (CPU) 1200, a user interface 1300 and a power supply device 1400, which perform data communication with each other through a bus 1500.

Here, the memory system 1100 may include a variable resistance memory device 1110 and a memory controller 1120. The variable memory device 1110 may store data processed by the CPU 1200 or data inputted from outside through the user interface 1300.

The information processing system 1000 may include all kinds of electronic devices required for data storage. For example, the information processing system 1000 may be applied to various mobile devices such as a memory card, a solid state disk (SSD), and a smart phone.

In accordance with the embodiments of the present invention, the contact plug between the variable resistance pattern forming memory cells and the active area becoming the source or drain area of a transistor is formed by the self-alignment method. Therefore, the mask process may be simplified, and fail occurrence may be prevented. For example, a rapid increase of contact resistance or contact not open due to misalignment of the mask pattern may be prevented. Furthermore, as the contact plug has a low aspect ratio, the electrical resistance may be reduced to lower the operating voltage of the variable resistance memory device.

While the present invention has been described with respect to the specific embodiments, it will be apparent to those skilled in the art that various changes and modifications may be made without departing from the spirit and scope of the invention as defined in the following claims.

What is claimed is:

1. A variable resistance memory device comprising:
a semiconductor substrate having an active area defined by an isolation layer extending in one direction;
a gate line extending in another direction crossing the isolation layer through the isolation layer and the active area;
a protective layer located over the gate line;
a contact plug positioned in a partially removed space of the active area between the protective layers; and
a variable resistance pattern coupled to a part of the contact plug.

2. The variable resistance memory device of claim 1, wherein the contact plug comprises an ohmic contact layer.

3. The variable resistance memory device of claim 1, wherein the isolation layer and the protective layer are formed of a material having an etching selectivity with the active area.

4. The variable resistance memory device of claim 1, wherein the active area has a larger width than the gate line.

5. The variable resistance memory device of claim 1, wherein the gate line crosses the active area at an angle of 60° to 120°.

6. The variable resistance memory device of claim 1, further comprising a bit line coupled to the variable resistance pattern and extending in a direction crossing the gate line.

7. The variable resistance memory device of claim 1, further comprising:
a source line contact plug coupled to the contact plug positioned between the variable resistance patterns; and
a source line coupled to the source line contact plug and extending in a direction crossing the gate line.

8. The variable resistance memory device of claim 1, wherein the variable resistance pattern comprises a magnetic tunnel junction (MTJ) structure whose electrical resistance is changed by a magnetic field or spin transfer torque (STT).

9. The variable resistance memory device of claim 1, wherein the variable resistance pattern comprises a structure whose electrical resistance is changed by migration of oxygen vacancies or ions or phase change of a material.

10. The variable resistance memory device of claim 6, further comprising:
a source line contact plug coupled to the contact plug positioned between the variable resistance patterns; and
a source line coupled to the source line contact plug and formed at a higher position than the bit line.

11. The variable resistance memory device of claim 6, further comprising:
a source line contact plug coupled to the contact plug positioned between the variable resistance patterns; and
a source line coupled to the source line contact plug and extending in the same direction on the same plane as the bit line.

12. The variable resistance memory device of claim 7, wherein the source line contact plug has a larger height than the variable resistance pattern.

13. A method for fabricating a variable resistance memory device, comprising:
providing a semiconductor memory device having an active area defined by an isolation layer extending in one direction;
forming a trench extending in a direction crossing the isolation layer by selectively etching the isolation layer and the active area;
forming a gate line and a protective layer over the gate line in the trench;
forming a contact hole by partially etching the active area between the protective layers;
forming a contact plug in the contact hole; and
forming a variable resistance pattern coupled to a part of the contact plug.

14. The method of claim 13, wherein the forming of the contact plug comprises forming an ohmic contact layer over the active area corresponding to the bottom surface of the contact hole.

15. The method of claim 13, wherein the isolation layer and the protective layer are formed of a material having an etching selectivity with the active area.

16. The method of claim 13, wherein the active area is formed to have a larger width than the gate line.

17. The method of claim 13, wherein the gate line is formed to cross the active area at an angle of 60° to 120°.

18. The method of claim 13, further comprising forming a bit line coupled to the variable resistance pattern and extending in a direction crossing the gate line.

19. The method of claim 13, further comprising:
forming a source line contact plug coupled to the contact plug positioned between the variable resistance patterns; and
forming a source line coupled to the source line contact plug and extending in a direction crossing the gate line.

20. The method of claim 13, wherein the variable resistance pattern comprises an MTJ structure whose electrical resistance is changed by a magnetic field or STT.

21. The method of claim 13, wherein the variable resistance pattern comprises a structure whose electrical resistance is changed by migration of oxygen vacancies or ions or phase change of a material.

22. The method of claim 18, further comprising:
forming a source line contact plug coupled to the contact plug positioned between the variable resistance patterns; and
forming a source line at a higher position than the bit line such that the source line is coupled to the source line contact plug.

23. The method of claim 18, further comprising:
forming a source line contact plug coupled to the contact plug positioned between the variable resistance patterns; and
forming a source line coupled to the source line contact plug and extending in the same direction on the same plane as the bit line.

24. The method of claim 19, wherein the source line contact plug has a larger height than the variable resistance pattern.

25. A semiconductor device, comprising:
a variable resistance pattern configured to store data with non-volatility;
a bit line configured to deliver data to/from the variable resistance pattern;
a word line configured to control data delivery between the bit line and the variable resistance pattern, including a buried gate line located at a level under a top surface of semiconductor substrate; and
a source line configured to supply operational voltage to the variable resistance pattern,
wherein a physical distance between the word line and the variable resistance pattern is shorter than that between the word line and the bit line.

26. The semiconductor device of claim 25, wherein the physical distance between the word line and the variable resistance pattern is shorter than that between the word line and the source line.

27. The semiconductor device of claim 25, wherein the source line is located higher than the bit line.

28. The semiconductor device of claim 25, wherein the bit line and the source line are located on the same plane.
